(19) United States
(12) Patent Application Publication
(10) Pub. No.: US 2026/0157083 A1
(43) Pub. Date: Jun. 4, 2026

(54) Display Device and Electronic Device Including Same

(71) Applicant: Samsung Display Co., Ltd., Yongin-si (KR)

(72) Inventors: Seung Yong Song, Yongin-si (KR); Oh June Kwon, Yongin-si (KR); Seung Yeon Chae, Yongin-si (KR)

(73) Assignee: Samsung Display Co., Ltd., Yongin-si (KR)

(21) Appl. No.: 19/317,792

(22) Filed: Sep. 3, 2025

(30) Foreign Application Priority Data
Nov. 29, 2024 (KR) 10-2024-0174328

(51) Int. Cl. H10K 59/80

(52) U.S. Cl. CPC H10K 59/873

(57) ABSTRACT

Provided is a display device and an electronic device comprising the same. A display device includes a display panel, the display panel having a substrate and an encapsulation inorganic film arranged on the substrate. A through hole is defined through the display panel, and there is a gap between one side of the substrate exposed by the through hole and one side of the encapsulation inorganic film exposed by the through hole.

### CROSS-REFERENCE TO RELATED APPLICATION

This application claims priority from Korean Patent Application No. 10-2024-0174328 filed on Nov. 29, 2024, the disclosure of which is incorporated by reference herein in its entirety.

### TECHNICAL FIELD

The present disclosure relates to a display device and an electronic device that incorporates such display device.

### BACKGROUND

With the advance of our information-oriented society, more and more demands are being placed on display devices to display images in various modes. For example, display devices are employed in various electronic devices such as smartphones, digital cameras, laptop computers, navigation devices, and smart televisions.

Many contemporary display devices include a light receiving display device such as a liquid crystal display device, a field emission display device, a light emitting display device, or the like. Light emitting display devices may be, for example, an organic light emitting display device including an organic light emitting element, an inorganic light emitting display device including an inorganic light emitting element such as an inorganic semiconductor or an ultra-small light emitting display device including an ultra-small light emitting element.

While use of the above-mentioned and other similar varieties of display devices is generally desirable, existing devices may suffer from inadequate durability. Accordingly, a need exists for display devices with improved durability.

### BRIEF SUMMARY

One aspect of the present disclosure provides a display device having improved durability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

A display device according to various embodiments of the present disclosure includes a display panel. The display panel includes a substrate and an encapsulation inorganic film arranged on the substrate. Further, a through hole is defined in the display panel. The substrate and the encapsulation inorganic film are arranged such that a gap is defined between one side of the substrate exposed by the through hole and one side of the encapsulation inorganic film exposed by the through hole.

In some examples, the display panel may include a through hole edge area adjacent to the through hole and an inorganic encapsulation area including a first dam and a second dam. A distance between the through hole and the second dam may be smaller than a distance between the through hole and the first dam, and the through hole edge area may be arranged between the through hole and the second dam. Further, a distance between the substrate and the encapsulation inorganic film may change moving away from the edge of the through hole into the through hole edge area.

In some examples, the through hole edge area may include a filler arranged between the substrate and the encapsulation inorganic film.

In some examples, a thickness of the filler may change moving away from the edge of the through hole into the through hole edge area.

In some examples, a thickness of the filler may decrease moving away from the edge of the through hole into the through hole edge area.

In some examples, a distance between the substrate and the encapsulation inorganic film may decrease moving away from the edge of through hole into the through hole edge area.

In some examples, the through hole edge area may include a common electrode remnant arranged between the substrate and the encapsulation inorganic film.

In some examples, a distance between the substrate and the common electrode remnant may change moving away from the edge of the through hole into the through hole edge area.

In some examples, a distance between the substrate and the common electrode remnant may decrease moving away from the edge of the through hole into the through hole edge area.

In some examples, the through hole edge area may include a light emitting layer remnant arranged between the substrate and the encapsulation inorganic film.

In some examples, the through hole edge area may include a filler arranged between the substrate and the encapsulation inorganic film.

In some examples, the light emitting layer remnant may include an upper light emitting layer remnant arranged between the encapsulation inorganic film and the filler.

In some examples, the light emitting layer remnant may include a lower light emitting layer remnant arranged between the substrate and the filler.

In some examples, the light emitting layer remnant may include a lower light emitting layer remnant arranged between the substrate and the filler.

In some examples, the filler may include a protrusion protruding into the through hole such that the protrusion protrudes relative to the edge of the through hole.

In some examples, a distance between the substrate and the upper light emitting layer remnant may change moving away from the edge of the through hole into the through hole edge area.

An electronic device according to various embodiments of the present disclosure includes a display device and a power module. The display device includes a display panel. The display panel of these embodiments includes a substrate and an encapsulation inorganic film arranged on the substrate. Further, a through hole is defined in the display panel and a gap is formed between one side of the substrate exposed by the through hole and one side of the encapsulation inorganic film exposed by the through hole. The power module is configured to supply power to the display device.

In some examples of the electronic device, the display panel may include a through hole edge area adjacent to the through hole and an inorganic encapsulation area with a first dam and a second dam. A distance between the through hole and the second dam may be smaller than a distance between the through hole and the first dam. The through hole edge area may be arranged between the through hole and the second dam, and a distance between the substrate and the encapsulation inorganic film may change moving away from the edge of the through hole into the through hole edge area.

In some examples of the electronic device, the through hole edge area may include a filler arranged between the substrate and the encapsulation inorganic film.

In some examples of the electronic device, a thickness of the filler may change moving away from the edge of the through hole into the through hole edge area.

According to embodiments of the present disclosure, damage due to detachment of a protective film may be reduced or prevented by including an arbitrarily formed gap.

According to embodiments of the present disclosure, damage to a light emitting layer in an edge area of a through hole, which may be vulnerable to detachment of the protective film, may be reduced or prevented by disposing a filler in the formed gap and then curing it. Such arrangement prevents damage to the light emitting layer so that subsequent etchants and the like may not permeate into a display area through the light emitting layer, and the durability of the display device may be improved.

### BRIEF DESCRIPTION OF THE DRAWINGS

The above and other aspects and features of the present disclosure will become more apparent by reading the following detailed description of non-limiting embodiments thereof, and with reference to the accompanying drawings, in which:

FIG. 1 is a plan view illustrating a display panel and a driving integrated circuit according to one embodiment of the present disclosure;

FIG. 2 is a cross-sectional view showing an example of a display device with a bent circuit board according to one embodiment of the present disclosure;

FIG. 3 is a cross-sectional view illustrating an example of a display area of a display panel according to one embodiment of the present disclosure;

FIGS. 4 and 5 are cross-sectional views illustrating one process step of a manufacturing process to manufacture a display device according to one embodiment of the present disclosure;

FIG. 6 is a close-up view of area I of FIG. 1;

FIG. 7 is a cross-sectional view schematically illustrating an example of a display panel taken along line X-X′ of FIG. 6;

FIG. 8 is a close-up view of area J of FIG. 6;

FIG. 9 is a cross-sectional view illustrating an example of a display panel taken along line Y-Y′ of FIG. 8;

FIG. 10 is a close-up view of area K of FIG. 9;

FIGS. 11, 12, 13, 14 and 15 are close-up views of respective embodiments that are modifications of FIG. 10;

FIG. 16 is a flowchart showing a method of manufacturing a display device according to one embodiment of the present disclosure;

FIGS. 17 to 18 are cross-sectional views illustrating respective steps in a method of manufacturing a display device according to one embodiment of the present disclosure;

FIG. 19 is a block diagram of an electronic device according to one embodiment of the present disclosure; and

FIG. 20 is schematic views of various electronic devices according to various embodiments of the present disclosure.

### DETAILED DESCRIPTION

The advantages and features of the embodiments disclosed herein, and methods of achieving them, will become apparent upon reference to the embodiments described in detail herein in conjunction with the accompanying drawings. However, the present disclosure is not limited to the example embodiments disclosed herein and may be implemented in various ways. The example embodiments are provided for illustrative purposes and for fully conveying the scope of the disclosure to those skilled in the art.

As used herein, the terms “substantially,” “generally,” “approximately,” and “about” are intended to mean that slight deviations from absolute are included within the scope of the term so modified. References to an element or layer as being “on” another element or layer include examples in which an element or layer is directly on the other element or layer, or examples where intervening layers may also be present. Throughout the present disclosure, like reference numerals refer to like elements. The shapes, sizes, proportions, angles, numbers, etc. disclosed in the drawings to illustrate embodiments are exemplary and are not intended to be limiting to those shown.

Although terms such as first, second, and the like are used to describe various components of the present disclosure, the components are not limited by these terms. Rather, these terms are used merely to distinguish one component from another. Thus, a first component referred to herein may, in some examples, be a second component within the technical scope of the present disclosure.

Each of the features of the various embodiments disclosed herein may be combined or combinable with each other, in part or in whole, and may be technically interlocked and operated in a variety of ways. Further, each embodiment may be practiced independently of or in conjunction with one or more other embodiments contemplated herein.

Hereafter, examples of embodiments of the present disclosure will be described in detail below with reference to the accompanying drawings. Configurations that function substantially the same between embodiments are given the same drawing designation and repeated description is omitted.

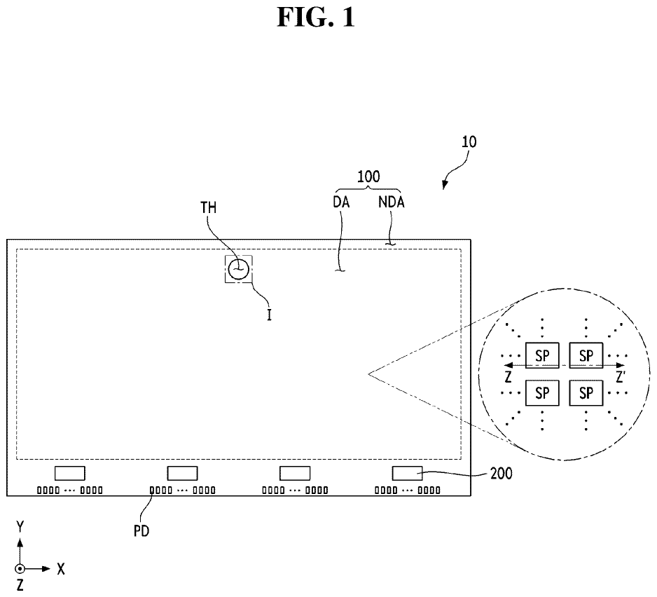

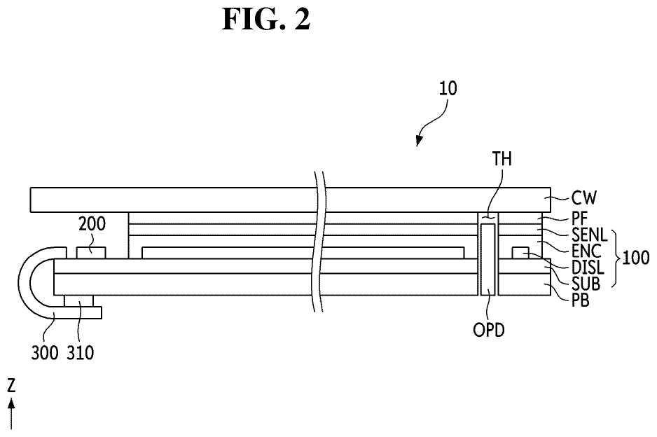

FIG. 1 is a plan view illustrating a display panel and a driving integrated circuit, also referred to as a “driving IC,” according to one embodiment of the present disclosure. FIG. 2 is a cross-sectional view showing an example of a display device in which a circuit board according to one embodiment of the present disclosure is bent.

Referring to FIGS. 1 and 2, a through hole TH may be formed in a display device 10 according to one embodiment of the present disclosure. The through hole TH may be a hole capable of transmitting light, and may penetrate a substrate SUB, a thin film transistor layer TFTL, an encapsulation layer ENC, and a sensor electrode layer SENL of the display panel 100. The through hole TH may be a physical hole penetrating not only a display panel 100 but also a panel lower cover PB and a polarizing film PF. However, the embodiments contemplated by the present disclosure are not limited thereto, and in some embodiments, the through hole TH may penetrate the panel lower cover PB but not the display panel 100 and the polarizing film PF. As shown in FIG. 2, the cover window CW may be disposed to cover the through hole TH.

According to some embodiments, and as shown in FIG. 2, an electronic device that includes the display device 10 may further include an optical device OPD disposed in the through hole TH. The electronic device according to one embodiment may be a portable electronic device such as a mobile phone, a smart phone, a tablet personal computer (PC), a smart watch, a watch phone, a mobile communication terminal, an electronic notebook, an electronic book, a portable multimedia player (PMP), a navigation device, or an ultra mobile PC (UMPC), as well as a television, a laptop computer, a monitor, a billboard, or an Internet of Things (IOT) device. However, the embodiments of the present disclosure are not limited thereto.

The optical device OPD may be spaced apart from the display panel 100, the panel lower cover PB, and the polarizing film PF. The optical device OPD may be an optical sensor that senses light incident through the through hole TH, where the optical sensor may be, for example, a proximity sensor, an illuminance sensor or a camera sensor.

Referring to FIG. 2, the display device 10 according to one embodiment of the present disclosure may include the display panel 100, the polarizing film PF, a cover window CW, and the panel lower cover PB. The display panel 100 may include the substrate SUB, a display layer DISL, the encapsulation layer ENC, and the sensor electrode layer SENL.

In some embodiments, the substrate SUB may be made of a hard material. For example, the substrate SUB may be made of glass. In some examples, the substrate SUB may be formed of ultra thin glass (UTG) having a thickness of approximately 200 μm or less. In some embodiments, the substrate SUB may be made of a flexible material. For example, the substrate SUB may be formed of polyimide.

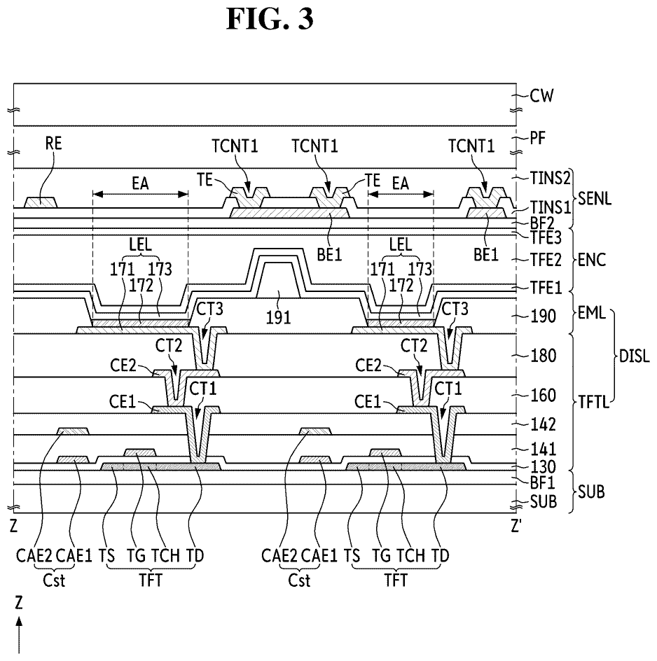

The display layer DISL may be disposed on the first surface of the substrate SUB. The display layer DISL may be a layer displaying an image. As shown in FIG. 3, the display layer DISL may include the thin film transistor layer TFTL in which thin film transistors are formed, and a light emitting element layer EML in which light emitting elements emitting light are disposed in emission areas.

In the display area DA of the display layer DISL, scan lines, data lines, power lines, or the like may be disposed so that the emission areas may emit light. In the non-display area NDA of the display layer DISL, a scan driving circuit unit outputting scan signals to the scan lines, fan-out lines connecting the data lines and the driving IC 200, and the like may be disposed.

The encapsulation layer ENC may prevent oxygen and/or moisture from permeating into the light emitting element layer EML of the display layer DISL. The encapsulation layer ENCL may be a layer for encapsulating the light emitting element layer EML of the display layer DISL. The encapsulation layer ENC may be disposed on the display layer DISL. In some examples, the encapsulation layer ENC may be disposed on the top surfaces and the side surfaces of the display layer DISL. The encapsulation layer ENC may be disposed to cover the display layer DISL.

The sensor electrode layer SENL may be disposed on the display layer DISL. The sensor electrode layer SENL may include sensor electrodes. The sensor electrode layer SENL may sense a user's touch through the inclusion of sensor electrodes.

The polarizing film PF may be disposed on the display panel 100 to reduce reflection of external light. The polarizing film PF may include a first base member, a linear polarization plate, a phase retardation film such as a quarter-wave plate (24 plate), and a second base member. The first base member, the phase retardation film, the linear polarization plate, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

The panel lower cover PB may be disposed on a second surface of the substrate SUB of the display panel 100. The second surface of the substrate SUB may be a surface opposite to the first surface. The panel lower cover PB may be attached to the second surface of the substrate SUB of the display panel 100 through an adhesive member. The adhesive member may be a pressure sensitive adhesive (PSA).

The panel lower cover PB may include one or more of a light blocking member for absorbing light incident from the outside, a buffer member for absorbing an impact from the outside, and a heat dissipation member for efficiently dissipating heat from the display panel 100.

The light blocking member may be disposed under the display panel 100. The light blocking member may block light transmission, thereby preventing components (e.g., a circuit board 300 and the like) disposed under the light blocking member from being viewed from the top of the display panel 100. The light blocking member may include a light absorbing material such as a black pigment, black dyes or the like.

The buffer member may be disposed under the light blocking member. The buffer member may absorb an external impact to prevent the display panel 100 from being damaged. The buffer member may be formed of a single layer or multiple layers. For example, the buffer member may be formed of a polymer resin such as polyurethane (PU), polycarbonate (PC), polypropylene (PP), or polyethylene (PE) or may include an elastic material such as a foamed sponge obtained from rubber, a urethane-based material, or an acrylic material.

The heat dissipation member may be disposed under the buffer member. The heat dissipation member may include a first heat dissipation layer containing graphite, carbon nanotubes or the like, and a second heat dissipation layer formed of a metal thin film containing, for example, copper, nickel, ferrite, or silver which can shield electromagnetic waves and has excellent thermal conductivity.

As shown in FIG. 2, the circuit board 300, disposed on the substrate SUB at one end, may be bent toward the bottom of the display panel 100. The circuit board 300 may be attached to the bottom surface of the panel lower cover PB by an adhesive member 310. The adhesive member 310 may be a pressure sensitive adhesive.

FIG. 3 is a cross-sectional view illustrating an example of a display area of a display panel according to one embodiment of the present disclosure. The view in FIG. 3 is based on a cross-section taken along line Z-Z′ of FIG. 1.

Referring to FIG. 3, the display panel 100 according to one embodiment of the present disclosure may be an organic light emitting display panel having a light emitting element LEL including an organic light emitting layer 172.

The display layer DISL may include the thin film transistor layer TFTL including a plurality of thin film transistors and the light emitting element layer EML including a plurality of light emitting elements.

A first buffer film BF1 may be disposed on the substrate SUB. The first buffer film BF1 may be formed of an inorganic material such as one of a silicon nitride layer, a silicon oxynitride layer, a silicon oxide layer, a titanium oxide layer and an aluminum oxide layer. Alternatively, the first buffer film BF1 may be formed as a multilayer structure that includes a plurality of layers including a silicon nitride layer, a silicon oxynitride layer, a silicon oxide layer, a titanium oxide layer and an aluminum oxide layer alternately stacked with respect to each other. In variations, other combinations of two or more of the mentioned compositions may be included in a plurality of layers of a multilayer structure.

An active layer including a channel region TCH, a source region TS, and a drain region TD of the thin film transistor TFT may be disposed on the first buffer film BF1. The active layer may be formed of polycrystalline silicon, monocrystalline silicon, low-temperature polycrystalline silicon, amorphous silicon, or an oxide semiconductor material. When the active layer includes polycrystalline silicon or an oxide semiconductor material, the source region TS and the drain region TD of the active layer may be conductive regions doped with ions or impurities and having conductivity.

The gate insulating film 130 may be disposed on the active layer of the thin film transistor TFT. The gate insulating film 130 may be formed of an inorganic film, for example, a silicon nitride layer, a silicon oxynitride layer, a silicon oxide layer, a titanium oxide layer, or an aluminum oxide layer.

A first gate metal layer including a gate electrode TG of the thin film transistor TFT, a first capacitor electrode CAE1 of a capacitor Cst, and scan lines may be disposed on the gate insulating film 130. The gate electrode TG of the thin film transistor TFT may overlap the channel region TCH in the third direction (e.g., Z-axis direction). The first gate metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A first interlayer insulating film 141 may be disposed on the first gate metal layer. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including a second capacitor electrode CAE2 of the capacitor Cst may be disposed on the first interlayer insulating film 141. The second capacitor electrode CAE2 may overlap the first capacitor electrode CAE1 in the third direction (e.g., Z-axis direction). Therefore, the capacitor Cst may be formed by the first capacitor electrode CAE1, the second capacitor electrode CAE2, and an inorganic insulating dielectric layer disposed therebetween to serve as a dielectric layer. The second gate metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second interlayer insulating film 142 may be disposed on the second gate metal layer. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include a plurality of inorganic films.

The first data metal layer including a first connection electrode CE1 and the data lines may be disposed on the second interlayer insulating film 142. The first connection electrode CE1 may be connected to the drain region TD through a first contact hole CT1 penetrating the gate insulating film 130, the first interlayer insulating film 141, and the second interlayer insulating film 142. The first data metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A first organic film 160 for flattening the stepped portion due to the thin film transistors TFT may be disposed on the first connection electrode CE1. The first organic film 160 may be formed of an organic film such as acryl resin, epoxy resin, phenolic resin, polyamide resin, polyimide resin and the like.

The second data metal layer including a second connection electrode CE2 may be disposed on the first organic film 160. The second data metal layer may be connected to the first connection electrode CE1 through a second contact hole CT2 penetrating the first organic film 160. The second data metal layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second organic film 180 may be disposed on the second connection electrode CE2. The second organic film 180 may be formed of an organic film such as acryl resin, epoxy resin, phenolic resin, polyamide resin, polyimide resin and the like.

In some examples, the second data metal layer including the second connection electrode CE2 and the second organic film 180 may be omitted.

The light emitting element layer EML may be disposed on the thin film transistor layer TFTL. The light emitting element layer EML may include light emitting elements LEL and a bank 190.

Each of the light emitting elements LEL may include a pixel electrode 171, the light emitting layer 172, and a common electrode 173. Each of the emission areas EA may be an area in which the pixel electrode 171, the light emitting layer 172, and the common electrode 173 are sequentially stacked such that the holes from the pixel electrode 171 and the electrons from the common electrode 173 are combined with each other to emit light. In this case, the pixel electrode 171 may be an anode electrode, and the common electrode 173 may be a cathode electrode.

A pixel electrode layer including the pixel electrode 171 may be formed on the second organic film 180. The pixel electrode 171 may be connected to the second connection electrode CE2 through a third contact hole CT3 penetrating the second organic film 180. The pixel electrode layer may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

In a top emission structure that emits light toward the common electrode 173 with respect to the light emitting layer 172, the pixel electrode 171 may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and Indium Tin Oxide (ITO), or a stacked structure (ITO/APC/ITO) of APC alloy and ITO to increase the reflectivity. The APC alloy is an alloy of silver (Ag), palladium (Pd) and copper (Cu).

The bank 190 serves to define the emission areas EA of the pixels. To this end, the bank 190 may be formed to expose a partial region of the pixel electrode 171 on the second organic film 180. The bank 190 may cover the edge of the pixel electrode 171. The bank 190 may be disposed in the third contact hole CT3. Put another way, the third contact hole CT3 may be filled with the bank 190. The bank 190 may be formed of an organic film such as acryl resin, epoxy resin, phenolic resin, polyamide resin, polyimide resin and the like.

A spacer 191 may be disposed on the bank 190. The spacer 191 may serve to support a mask during a process of manufacturing the light emitting layer 172. The spacer 191 may be formed of an organic film such as acryl resin, epoxy resin, phenolic resin, polyamide resin, polyimide resin and the like.

The light emitting layer 172 may be formed on the pixel electrode 171. The light emitting layer 172 may include an organic material to emit light of a predetermined color. For example, the light emitting layer 172 may include a hole transporting layer, an organic material layer, and an electron transporting layer. The organic material layer may include a host and a dopant. The organic material layer may include a material that is configured to emit predetermined light, and may be formed using a phosphorescent material or a fluorescent material.

The common electrode 173 may be formed on the light emitting layer 172. The common electrode 173 may be formed to cover the light emitting layer 172. The common electrode 173 may be a common layer formed in common on the emission areas EA. A capping layer may be formed on the common electrode 173.

In the top emission structure, the common electrode 173 may be formed of a transparent conductive material (TCO) such as ITO or Indium Zinc Oxide (IZO) capable of transmitting light or a semi-transmissive conductive material such as magnesium (Mg), silver (Ag), or an alloy of magnesium (Mg) and silver (Ag). When the common electrode 173 is formed of a semi-transmissive conductive material, the light emission efficiency can be increased due to a micro-cavity effect.

The encapsulation layer ENC may be formed on the light emitting element layer EML. The encapsulation layer ENC may include at least one inorganic film TFE1 and TFE3 to prevent oxygen or moisture from permeating into the light emitting element layer EML. In addition, the encapsulation layer ENC may include at least one organic film to protect the light emitting element layer EML from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may each be formed of multiple films in which one or more inorganic films of a silicon nitride layer, a silicon oxynitride layer, a silicon oxide layer, a titanium oxide layer and an aluminum oxide layer are alternately stacked. In other examples, multiple film configurations may include other arrangements of compositions including one or more of the above-mentioned compositions. The encapsulation organic film TFE2 may be an organic film such as acryl resin, epoxy resin, phenolic resin, polyamide resin, polyimide resin or the like.

The sensor electrode layer SENL is disposed on the encapsulation layer ENC. The sensor electrode layer SENL may include sensor electrodes TE and RE.

A second buffer film BF2 may be disposed on the encapsulation layer ENC. The second buffer film BF2 may include at least one inorganic film. For example, the second buffer film BF2 may be formed of multiple films in which one or more inorganic films of a silicon nitride layer, a silicon oxynitride layer, a silicon oxide layer, a titanium oxide layer and an aluminum oxide layer are alternately stacked. In other examples, multiple film configurations may include other arrangements of compositions including one or more of the above-mentioned compositions. In some examples, the second buffer film BF2 may be omitted.

First connection portions BE1 may be disposed on the second buffer film BF2. The first connection portions BE1 may be formed of a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

A first sensor insulating film TINS1 may be disposed on the first connection portions BE1. The first sensor insulating film TINS1 may be formed of an inorganic film, for example, a silicon nitride layer, a silicon oxynitride layer, a silicon oxide layer, a titanium oxide layer, or an aluminum oxide layer.

The sensor electrodes, that is, the driving electrodes TE and the sensing electrodes RE may be disposed on the first sensor insulating film TNIS1. In addition, dummy patterns may be disposed on the first sensor insulating film TNIS1. The driving electrodes TE, the sensing electrodes RE, and the dummy patterns do not overlap the emission areas EA. The driving electrodes TE, the sensing electrodes RE, and the dummy patterns may be formed of a single layer containing molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and indium tin oxide (ITO), an Ag—Pd—Cu (APC) alloy, or a stacked structure (ITO/APC/ITO) of APC alloy and ITO.

A second sensor insulating film TINS2 may be disposed on the driving electrodes TE, the sensing electrodes RE, and the dummy patterns. The second sensor insulating film TINS2 may include at least one of an inorganic film or an organic film. The inorganic film may be a silicon nitride layer, a silicon oxynitride layer, a silicon oxide layer, a titanium oxide layer, or an aluminum oxide layer. The organic film may include acryl resin, epoxy resin, phenolic resin, polyamide resin, or polyimide resin.

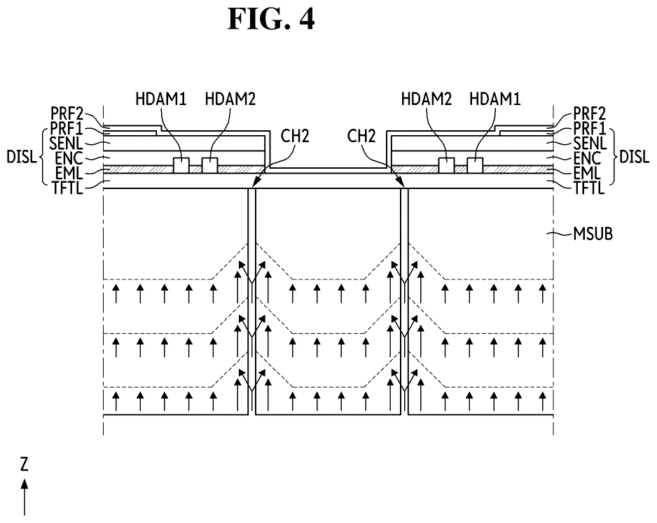

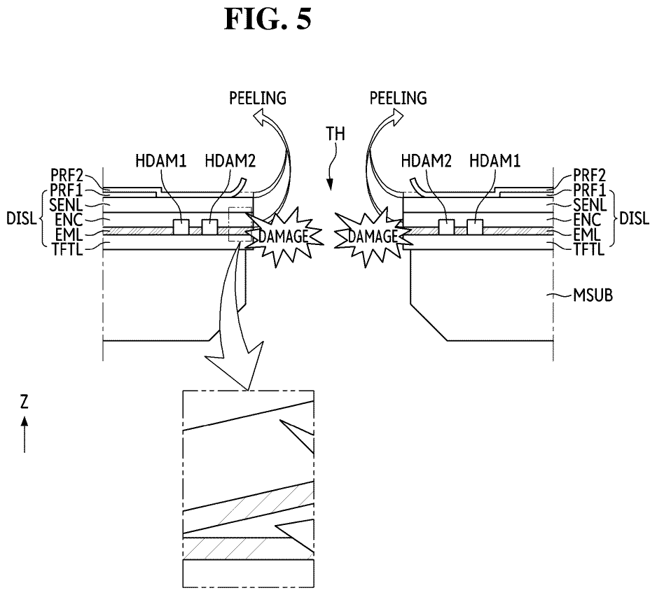

FIGS. 4 and 5 are cross-sectional views illustrating one sub-process of a process of manufacturing a display device according to one embodiment of the present disclosure. In some examples, the process of manufacturing may include a plurality of steps.

In one step, a plurality of display cells may be formed on a first surface of a mother substrate MSUB.

In a subsequent step, a plurality of first protective films PRF1 may be attached onto the plurality of display cells. Each of the plurality of first protective films PRF1 may be a buffer film for protecting the plurality of display cells DPC from external impact. In some examples, the plurality of first protective films PRF1 may be made of a transparent material. Further, in some examples, the plurality of display cells may be inspected.

In a subsequent step, a first laser may be irradiated on a second surface facing the first surface of the mother substrate MSUB. Through such irradiation, a plurality of first laser irradiation areas disposed along the edges of each display cell of the plurality of display cells may be formed. Various lasers may be used as the laser according to some embodiments.

The laser for forming the first laser irradiation areas may be irradiated with a repetition rate within a range of 10 kHz to 250 kHz, a processing speed within a range of 10 mm/s to 250 mm/s, and pulse energy within a range of 10 uJ to 300 uJ. However, in order for the laser to have a depth of approximately 225 μm from the first surface of the mother substrate MSUB, it may be preferable to perform irradiation with a repetition rate within a range of approximately 17.5 kHz to 125 kHz, a processing speed within a range of 17.5 mm/s to 125 mm/s, and pulse energy within a range of 25 uJ to 178 uJ.

In a subsequent step, a second laser may be irradiated on the second surface of the mother substrate MSUB. A plurality of second laser irradiation areas CH2 for forming a through hole in each display cell of the plurality of display cells may be formed. In one embodiment, the first laser and the second laser may be irradiated simultaneously by a plurality of laser devices in order to shorten a process time.

A second cutting line may be defined as an imaginary line that connects the plurality of second laser irradiation areas CH2 in plan view. The second cutting line may be formed by irradiating the second laser to form the plurality of second laser irradiation areas CH2 along the edge of the through hole TH. The second cutting line may depend on the form and/or shape of the through hole. For example, when the through hole TH has a circular shape in plan view, the second cutting line may be formed in a circular shape.

Although various lasers may be used as the first laser and the second laser according to the embodiments contemplated by the present disclosure, a case in which the first laser and the second laser are infrared Bessel beams having a wavelength of approximately 1030 nm is illustrated in the figures of the present disclosure.

The depth of each of the plurality of first laser irradiation areas formed by the first laser and the depth (or sketch length) of each of the plurality of second laser irradiation areas CH2 formed by the second laser may be different. The depth of the first laser irradiation area may be defined as the depth (or sketch length) of the first laser irradiation area, and the depth of the second laser irradiation area CH2 may be defined as the depth (or sketch length) of the second laser irradiation area CH2.

In a subsequent step, and with reference to FIG. 4, a second protective film PRF2 may be attached on each film of the plurality of first protective films PRF1.

The second protective film PRF2 may be attached to each film of the plurality of first protective films PRF1 and the exposed mother substrate MSUB that is not covered by the plurality of first protective films PRF1. The second protective film PRF2 may cover the plurality of first laser irradiation areas and the plurality of second laser irradiation areas CH2. The second protective film PRF2 may be an acid-resistant film for protecting the plurality of display cells from the etchant in an etching process performed on the mother substrate MSUB, where the etching process may be performed in a subsequent step, as described below.

In a subsequent step, and with continued reference to FIG. 4, an etchant may be sprayed on the second surface of the mother substrate MSUB without a separate mask. Accordingly, the thickness of the mother substrate MSUB may be reduced.

Further, the mother substrate may be cut along the plurality of first laser irradiation areas and second laser irradiation areas CH2.

When the etchant is sprayed on the second surface of the mother substrate MSUB, the mother substrate MSUB may be reduced from a first thickness to a second thickness. Since the mother substrate MSUB is etched without a separate mask, the mother substrate MSUB may be uniformly etched over the entire area of the second surface of the mother substrate MSUB.

Each second laser irradiation area of the plurality of second laser irradiation areas CH2 may include a physical hole formed by the second laser and an area around the physical hole having physical properties that are changed by the laser. Alternatively, each second laser irradiation area of the plurality of second laser irradiation areas CH2 may be an area having physical properties that are changed by the second laser without forming a physical hole. Accordingly, the etching rate by the etchant in each second laser irradiation area of the plurality of second laser irradiation areas CH2 may be higher than the etching rate in other areas of the mother substrate MSUB to which the laser is not irradiated.

Since the depth of each second laser irradiation area of the plurality of second laser irradiation areas CH2 is greater than the depth of each first irradiation area of the plurality of first laser irradiation areas, the etchant may permeate into the plurality of second laser irradiation areas CH2 before it permeates into the plurality of first laser irradiation areas. That is, since the plurality of second laser irradiation areas CH2 are etched along with a slimming process in which the thickness of the mother substrate MSUB is reduced by the etchant, a tapered cross-section may be formed on the substrate SUB by isotropic etching in the through hole TH formed by the second laser irradiation area CH2. In contrast, the plurality of first laser irradiation areas may remain unaffected by any etching, i.e., may not be etched when the slimming of the mother substrate MSUB progresses.

In a subsequent step, referring to FIG. 5, after the etching process is completed, the second protective film PRF2 may be peeled. In the process of peeling the second protective film PRF2, one side of the second protective film PRF2 that is cut may be lifted. The one side may be adjacent to the through hole TH. Further, a driving IC and a circuit board are attached to each display cell of the plurality of display cells, and the first protective film PRF1 may be peeled in each display cell of the plurality of display cells.

When one side of the second protective film PRF2 is peeled, the adhesive strength between the second protective film PRF2 and the display layer DISL may affect components disposed under the second protective film PRF2. For example, the light emitting element layer EML disposed under the second protective film PRF2 may be damaged during the process of peeling the second protective film PRF2 disposed thereabove. The length of the light emitting element layer EML in a thickness direction (e.g., Z-axis direction) may be less than a length of other components SENL and ENC in the thickness direction. For example, the light emitting layer disposed in the light emitting element layer EML may be very thin. Therefore, damage due to the force necessary to overcome the adhesive strength of the second protective film PRF2 in order to peel it may occur relatively frequently.

Referring to the enlarged view included in FIG. 5, when one side of the light emitting element layer EML is separated into an upper part and a lower part, one side of the sensor electrode layer SENL and the encapsulation layer ENC may be lifted toward the upper side of the display device together with the upper part of the light emitting element layer EML of the separated light emitting element layer EML. As a result, a gap may form between the upper part and the lower part of the light emitting element layer EML.

When a gap forms in the light emitting element layer EML during the peeling process of the second protective film PRF2, moisture and/or oxygen may permeate into the gap, which may have an affect even on the display area. Accordingly, the durability of the display device may be diminished and otherwise lessened in such circumstances.

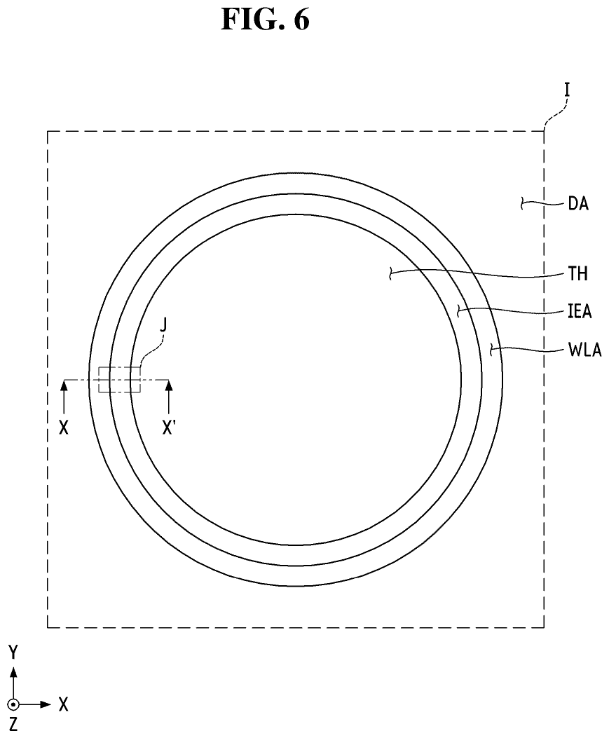

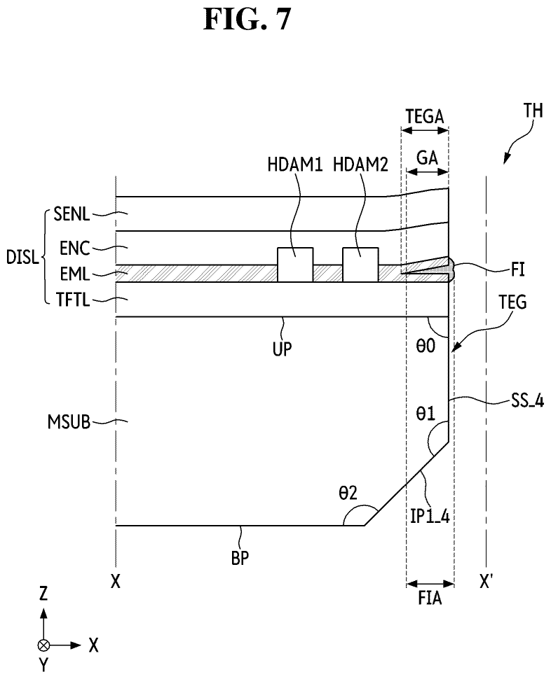

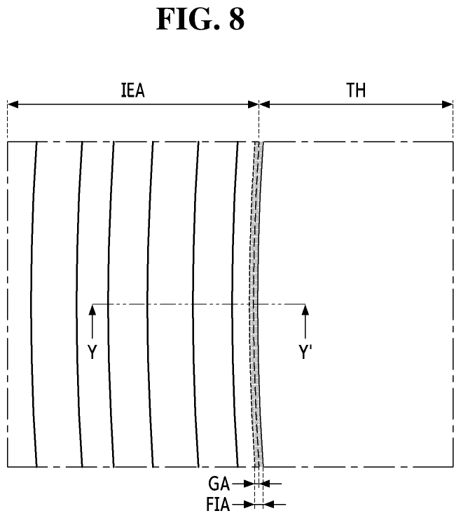

FIG. 6 is a close-up partial view of the display device 10 of FIG. 1, and more specifically, area I of FIG. 1. FIG. 7 is a cross-sectional view schematically illustrating an example of a display panel taken along sectional line X-X′ of FIG. 6. FIG. 8 is a close-up partial view of the display area of FIG. 6, and more specifically, area J of FIG. 6.

Referring to FIGS. 6 and 7, the display panel according to one embodiment of the present disclosure may include an inorganic encapsulation area IEA surrounding the through hole TH and a wiring area WLA surrounding the inorganic encapsulation area IEA.

The inorganic encapsulation area IEA may be a layer for preventing oxygen or moisture from permeating into the light emitting element layer EML of the display layer DISL due to the presence of the through hole TH. For example, the first encapsulation inorganic film TFE1 and the second encapsulation inorganic film TFE3 of the encapsulation layer ENC may be in contact with each other to prevent the permeation of oxygen or moisture therethrough.

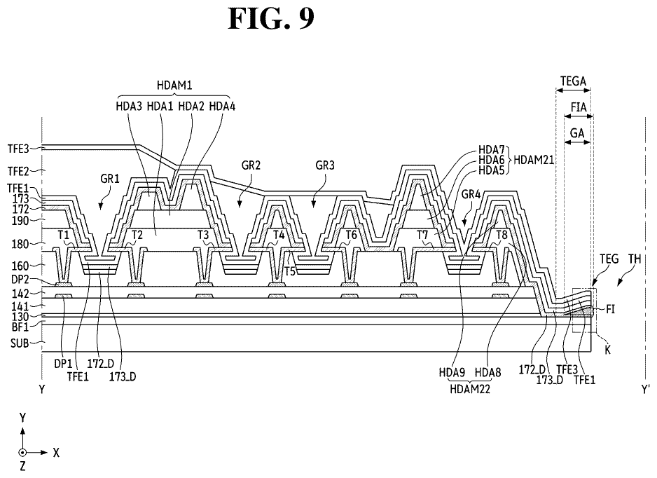

In some examples, the inorganic encapsulation area IEA may include at least one dam, at least one tip (e.g., tips T1 to T8 as shown in FIG. 9), and at least one groove (e.g., GR1 to GR4 as shown in FIG. 9). As depicted in FIG. 7, a first dam HDAM1 and a second dam HDAM2 are disposed on the thin film transistor layer TFTL, where the second dam HDAM2 is closer to the through hole TH than the first dam HDAM1.

The wiring area WLA may be an area in which bypass lines are disposed, the bypass lines being included due to the through hole TH. Some of the bypass lines may be connected to data lines, and some others of the bypass lines may be connected to a second power line to which a second source voltage higher than the first source voltage is applied. Additionally, other bypass lines may be connected to the scan lines. As shown in FIG. 6, the wiring area WLA may be surrounded by the display area DA.

Referring to FIGS. 7 and 8, FIG. 7 shows a cross-section of an edge TEG of the through hole TH when a substrate of a display panel is cut by irradiating a laser and then spraying an etchant. FIG. 8 is a close-up plan view of the display area DA of FIG. 6, including the through hole TH, and more specifically, area J of FIG. 6.

When cutting the substrate SUB by spraying an etchant after irradiating a laser, a through hole edge area TEGA may be formed. The through hole edge area TEGA may be an area where processing traces are formed on a top surface UP of the substrate SUB by an etchant. In some examples, a width of the through hole edge area TEGA may be approximately 30 μm.

The through hole edge area TEGA may include a first inclined surface IP1_4 formed by spraying the etchant after laser irradiation. In some examples, an angle θ0 between a side surface SS_4 of the edge TEG of the through hole TH and the top surface UP may be approximately 90 degrees. That is, an angle between the side surface SS_4 of the edge TEG of the through hole TH and the top surface UP may be such that side surface SS_4 is substantially close to vertical. An angle θ1 between the side surface SS_4 of the edge TEG of the through hole TH and the first inclined surface IP1_4 and an angle θ2 between the first inclined surface IP1_4 and the bottom surface BS may both be obtuse angles. The processing traces formed on the top surface UP of the substrate SUB may overlap the first inclined surface IP1_4 in the third direction (e.g., Z-axis direction).

The angle θ1 between the side surface SS_4 of the edge TEG of the through hole TH and the first inclined surface IP1_4 and the angle θ2 between the second inclined surface IP1_2 and the bottom surface BS may vary according to the depth of the laser irradiation area formed by the laser when the substrate SUB of the display panel 100 is cut by spraying the etchant after laser irradiation. The depth of the laser irradiation area formed by the laser to perform cutting along the edge TEG of the display panel 100 may be different from the depth of the laser irradiation area formed by the laser to perform cutting along the edge TEG of the through hole TH.

The display device according to one embodiment of the present disclosure may include a gap GA formed in the edge TEG of the through hole TH. The gap GA may be formed between one side of the substrate SUB exposed by the through hole TH and one side of the encapsulation layer ENC exposed by the through hole TH. The gap GA may be formed between the one side of the substrate SUB exposed by the through hole TH and one side of the light emitting element layer EML exposed by the through hole TH. Alternatively, it may be formed between separated upper and lower portions of the light emitting element layer EML.

As shown in FIG. 7, the gap GA may be defined from a side of the light emitting element layer EML exposed by the through hole TH to an enclosed end defined by a convergence of the separated upper and lower portions of the light emitting element layer EML. The gap GA may extend in a first direction (e.g., X-axis direction). The gap GA may have a length that surrounds the through hole TH in plan view (e.g., see FIG. 8).

The gap GA may refer to a space formed in a third direction (e.g., Z-axis direction) between one side of the substrate SUB and one side of the encapsulation layer ENC. The gap GA may overlap the through hole edge area TEGA when viewed in a display device plane (i.e., surface in XY plane).

With continued reference to FIG. 7, a filler FI may be disposed in the gap GA. The filler FI may be disposed between the substrate SUB and the encapsulation layer ENC. At least a part of the area where the filler FI is disposed may overlap the gap GA in the display device plane.

The gap GA formed in the display device according to embodiments of the present disclosure is not caused by tearing that may occur with the use of previously existing manufacturing processes. Rather, as will be described herein, the gap GA according to embodiments of the present disclosure may be arbitrarily formed before detaching the second protective film from the display panel.

In one embodiment, the filler FI may be in a cured state. The filler FI may include at least one of an epoxy resin, a UV resin, a polyurethane resin, a silicone resin, and a silica filler. However, the material is not limited thereto, and any material that may be applied to the gap GA in a soft state and then cured to fix the component disposed on top of the filler FI to the component disposed on the bottom of the filler FI is sufficient.

If the filler FI is applied to the arbitrarily formed gap GA and cured before detaching the second protective film PRF2, the adhesion within the through hole edge area TEGA, which is particularly vulnerable to tearing, may be improved by the filler FI. Due to the improved adhesion of the layers and other components within the through hole edge area TEGA, the formation of a gap due to tearing may be avoided when the second protective film is detached, e.g., peeled away. Accordingly, the probability of moisture or oxygen permeation into the through hole edge area TEGA via the through hole TH may be reduced and the durability of the display device may be improved.

The display device according to at least some embodiments of the present disclosure may include the gap GA formed before detachment of the second protective film from the display panel to reduce or prevent moisture (or oxygen) permeation into the display device and to prevent tearing in areas peripheral to the through hole TH, thereby preventing the generation of a gap or gaps.

FIG. 9 is a partial cross-sectional view illustrating an example of a display panel taken along line Y-Y′ of FIG. 8.

In the illustrated example, the cross-sectional view taken along line Y-Y′ includes the light emitting layer 172, the common electrode 173, the second organic film 180, the bank 190, and the like. Since this cross-sectional view spans between the display area and the through hole, the above-described components may be arranged in various ways other than exactly as shown in FIG. 9. However, the arrangement shown in FIG. 9 is instructive for understanding a correlation between the inorganic encapsulation area IEA in FIG. 9 and the display area DA shown in the above-described cross-sectional view taken along line Z-Z′ and shown in FIG. 3.

For example, to be precise, the second organic film 180 shown in the cross-sectional view may be any one sub-dam, the bank 190 may be another sub-dam, the light emitting layer 172 may be a light emitting layer remnant disposed in the extended portion of the broken region without actually emitting light, and the common electrode 173 may be a common electrode remnant disposed in the extended portion of the broken region without actually performing the function of an electrode.

It should be appreciated that the reference numerals in FIG. 9 are designated as illustrated in order to directly show the correlation with the light emitting element disposed in the display area in the drawing, and are not limiting.

Referring to FIG. 9, a first dummy pattern DP1 may include the same material as the second gate metal layer including the second capacitor electrode CAE2 of the capacitor Cst and may be disposed on the same layer. For example, the first dummy pattern DP1 may be disposed on the first interlayer insulating film 141. The first dummy pattern DP1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

A second dummy pattern DP2 may include the same material as the first data metal layer including the first connection electrode CE1 and the data lines and may be disposed on the same layer. For example, the second dummy pattern DP2 may be disposed on the second interlayer insulating film 142. The second dummy pattern DP2 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second dummy pattern DP2 may overlap the first dummy pattern DP1 in the third direction (e.g., Z-axis direction).

The first to eighth tips T1 to T8 may include the same material as the second data metal layer including the second connection electrode CE2 and may be disposed on the same layer. For example, the first to eighth tips T1 to T8 may be disposed on the first organic film 160. The first to eighth tips T1 to T8 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

Each of the first to eighth tips T1 to T8 may be connected to the second dummy pattern DP2 through a contact hole penetrating the first organic film 160. Each of the first to eighth tips T1 to T8 may include an eaves structure in which the top surface and the bottom surface are exposed without being covered by the first organic film 160, the second organic film 180, a first dam HDAM1, and a second-first dam HDAM21. For example, the plurality of tips may be formed integrally, similarly to the fourth tip T4 and the fifth tip T5. Each of the first to eighth tips T1 to T8 may be a protruding pattern or a trench pattern for forming a groove (or trench). The eighth tip T8 may be an outermost structure adjacent to the edge TEG of the through hole TH. As illustrated, the eighth tip T8 is exemplified as an outermost structure adjacent to the edge TEG of the through hole TH, but the present disclosure is not limited thereto. For example, if the seventh tip T7 and the eighth tip T8 are omitted, the outermost structure adjacent to the edge TEG of the through hole TH may be the second-first dam HDAM21 for preventing overflow of the encapsulation organic film TFE2 of the encapsulation layer ENC. Alternatively, if the seventh tip T7 and the eighth tip T8 are omitted, the outermost structure adjacent to the edge TEG of the through hole TH may be a groove for cutting off the light emitting layer 172 and the common electrode 173.

A distance from the eighth tip T8 to the edge TEG of the through hole TH may be approximately 300 μm. The through hole edge area TEGA may be disposed between the eighth tip T8 and the edge TEG of the through hole TH.

The first groove GR1 may be formed between the first tip T1 and the second tip T2, the second groove GR2 may be formed between the third tip T3 and the fourth tip T4, the third groove GR3 may be formed between the fifth tip T5 and the sixth tip T6, and the fourth groove GR4 may be formed between the seventh tip T7 and the eighth tip T8. The first groove GR1 may have an eaves structure formed by the first tip T1 and the second tip T2, the second groove GR2 may have an eaves structure formed by the third tip T3 and the fourth tip T4, the third groove GR3 may have an eaves structure formed by the fifth tip T5 and the sixth tip T6, and the fourth groove GR4 may have an eaves structure formed by the seventh tip T7 and the eighth tip T8.

Since the light emitting layer 172 is deposited by evaporation and the common electrode 173 is deposited by sputtering, the light emitting layer 172 and the common electrode 173 may be disposed to be broken at each of the first to fourth grooves GR1, GR2, GR3, and GR4 because the step coverage is low. In contrast, the first encapsulation inorganic film TFE1 and the third encapsulation inorganic film TFE3 may be deposited by chemical vapor deposition, atomic layer deposition, or the like, and thus may be formed to be continuous without being broken in each of the first to fourth grooves GR1, GR2, GR3, and GR4 because the step coverage is high. Step coverage refers to the ratio of the degree of thin film coated on an inclined portion to the degree of thin film coated on a flat portion. The light emitting layer 172, a broken light emitting layer remnant 172_D, the common electrode 173, and a broken common electrode remnant 173_D may be disposed in the first to fourth grooves GR1, GR2, GR3, and GR4, respectively.

The first dam HDAM1 may include a plurality of sub-dams including first to fourth sub-dams HDA1, HDA2, HDA3, and HDA4. Although it is illustrated that the first dam HDAM1 includes only four sub-dams HDA1, HDA2, HDA3, and HDA4, the embodiments of the present disclosure are not limited thereto. For example, the first dam HDAM1 may include three sub-dams, similarly to the second-first dam HDAM21.

The first sub-dam HDA1 may be disposed on the first organic film 160 and may include the same material as the second organic film 180. The first sub-dam HDA1 may be disposed on the second tip T2 and the third tip T3. The second sub-dam HDA2 may be disposed on the first sub-dam HDA1 and may include the same material as the bank 190. The third sub-dam HDA3 and the fourth sub-dam HDA4 may be disposed on the second sub-dam HDA2 and may include the same material as the spacer, but the materials are not limited thereto. The fourth sub-dam HDA4 may be disposed closer to the through hole TH than the third sub-dam HDA3. The thickness of the fourth sub-dam HDA4 may be greater than the thickness of the third sub-dam HDA3, but the embodiments of the present disclosure are not limited thereto.

The second-first dam HDAM21 may include fifth to seventh sub-dams HDA5, HDA6, and HDA7. The second-first dam HDAM21 may include four sub-dams similarly to the first dam HDAM1.

The fifth sub-dam HDA5 may be disposed on the first organic film 160 and may include the same material as the second organic film 180. The fifth sub-dam HDA5 may be disposed on the seventh tip T7. The sixth sub-dam HDA6 may be disposed on the fifth sub-dam HDA5 and may include the same material as the bank 190. The seventh sub-dam HDA7 may be disposed on the sixth sub-dam HDA6 and may include the same material as the spacer, but the materials are not limited thereto.

The second-second dam HDAM22 may include the eighth and ninth sub-dams HDA8 and HDA9. The second-second dam HDAM22 may also include four sub-dams similarly to the first dam HDAM1.

The eighth sub-dam HDA8 may be disposed on the first organic film 160 and may include the same material as the second organic film 180. The eighth sub-dam HDA8 may be disposed on the eighth tip T8. The ninth sub-dam HDA9 may be disposed on the eighth sub-dam HDA8 and may include the same material as the bank 190. In one embodiment, a separate sub-dam containing the same material as the spacer may be disposed on the ninth sub-dam HDA9, but the present disclosure is not limited thereto.

The encapsulation organic film TFE2 may be prevented from overflowing into the through hole TH by the first dam HDAM1, the second-first dam HDAM21, and the second-second dam HDAM22.

In the display device according to one embodiment of the present disclosure, the gap GA may be disposed between the through hole TH and a dam closest to the through hole TH. For example, the dam with the smallest distance to the through hole TH may be the second-second dam HDAM22 among the aforementioned dams. In this case, the gap GA according to the embodiment may be disposed between the second-second dam HDAM22 and the through hole TH. As described above, in the process of forming the through hole TH without use of the concepts contemplated by the present disclosure, tearing of the light emitting element layer EML may occur when the second protective film is removed from the cut side of the second protective film. The tearing may occur due to adhesion in the process of removing the second protective film.

Therefore, the gap GA according to one embodiment of the present disclosure may be formed in an area that may be a starting point for removing the second protective film and a cause of moisture or oxygen permeation. For example, the gap GA may be formed in the through hole edge area TEGA. The filler FI may be disposed in the formed gap GA.

As shown, the gap GA of the display device according to some embodiments of the present disclosure may be formed to completely overlap the through hole edge area TEGA. However, without being limited thereto, the size, extension length or the like of the gap GA may be changed in various ways. For example, the end portion of the gap GA (e.g., the portion where the separated light emitting layer remnants 172_D merge into one) may be extended to one end portion of the first interlayer insulating film 141 and/or the second interlayer insulating film 142.

Considering the actually realized thickness of the first interlayer insulating film 141, the second interlayer insulating film 142, and the gate insulating film 130 and the actually realized thickness of the light emitting layer remnant 172_D, in some examples, the end portion of the gap GA may be disposed to extend to the eighth tip T8.

The light emitting layer remnant 172_D, the common electrode remnant 173_D, the first encapsulation inorganic film TFE1, and the second encapsulation inorganic film TFE3 may extend to the edge TEG of the through hole TH. The end of the light emitting layer remnant 172_D, the end of the common electrode remnant 173_D, the end of the first encapsulation inorganic film TFE1, or the end of the second encapsulation inorganic film TFE3 may coincide with the edge TEG of the through hole TH.

Because the light emitting layer 172 and the common electrode 173 are broken in the first to fourth grooves GR1, GR2, GR3, and GR4 formed by the first to eighth tips T1 to T8, respectively, it is possible to prevent the light emitting layer 172 and the common electrode 173 exposed through the through hole TH from being a path through which oxygen, moisture, or the like permeates.

In one embodiment, an organic planarization layer may be disposed on the encapsulation layer ENC. With the inclusion of the organic planarization layer, a polarizing film may be easily attached onto the organic planarization layer.

The organic planarization layer may be formed of an organic film such as acryl resin, epoxy resin, phenolic resin, polyamide resin, polyimide resin and the like. For example, the organic planarization layer and the second sensor insulating film described above may include the same material, and may be formed simultaneously by the same process.

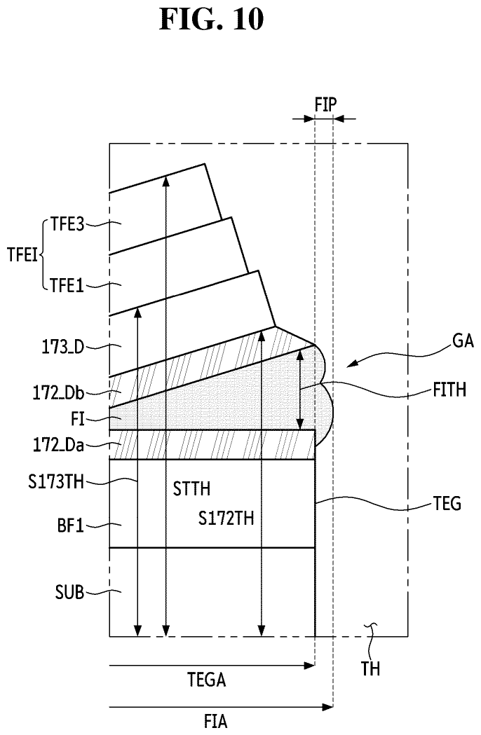

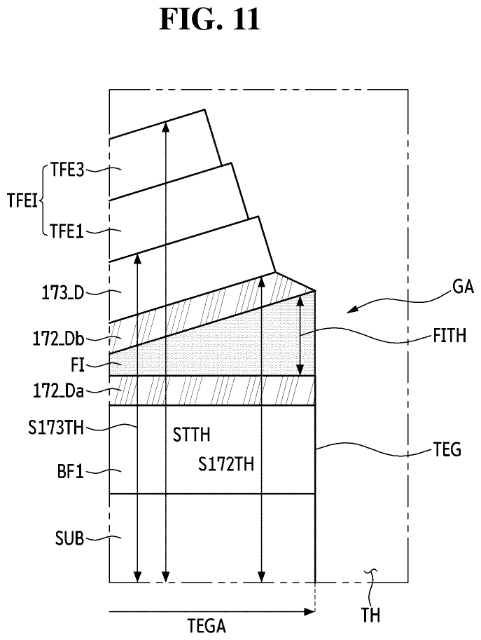

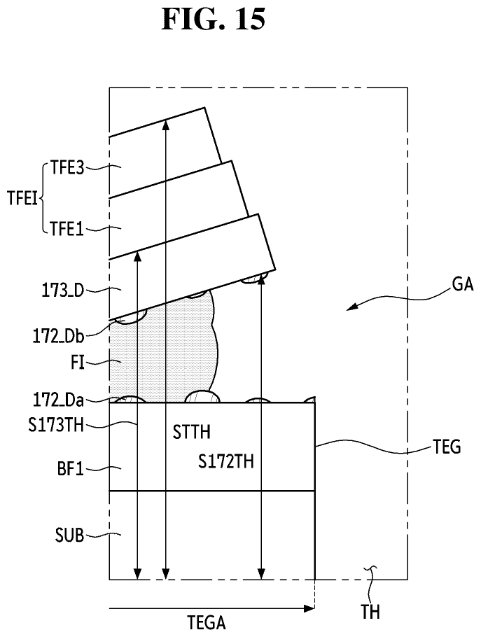

FIG. 10 is an enlarged view of area K of FIG. 9. FIGS. 11 to 15 are enlarged views of various embodiments based on modifications of FIG. 10. In FIGS. 11 to 15, unless otherwise noted, like reference numerals with respect to the reference numerals indicated in FIG. 10 refer to like elements.

Referring to FIG. 10, the display device according to one embodiment of the present disclosure may include the gap GA. The filler FI may be disposed in the gap GA. The through hole edge area TEGA may be disposed between the through hole TH and a second dam closest to the through hole TH. The gap GA may be disposed in the through hole edge area TEGA.

In the depicted embodiment, a direction from the through hole TH to the through hole edge area TEGA may be defined. In FIG. 10, according to the position of the arbitrarily shown cut line, the direction may be represented as the first direction (e.g., X-axis direction), approximately orthogonal to a length direction of the through hole TH. However, the present disclosure is not limited thereto. When the through hole TH is formed in a circular shape, the direction from the through hole TH to the through hole edge area TEGA may be any direction from the center of the through hole TH toward the display area. The direction from the through hole TH to the through hole edge area TEGA may vary according to the shape of the through hole TH.

In some embodiments, a distance STTH between the substrate SUB and an encapsulation inorganic film TFE1 may be defined. The encapsulation inorganic film TFE1 may be included in the aforementioned encapsulation layer. The encapsulation inorganic film TFE1 may include the first encapsulation inorganic film TFE1 and the second encapsulation inorganic film TFE3. Due to the formed gap GA, the distance between the substrate SUB and the encapsulation inorganic film TFE1 may vary in the direction from the through hole TH into the through hole edge area TEGA. For example, the distance between the substrate SUB and the encapsulation inorganic film TFE1 may decrease moving away from the through hole TH and into the through hole edge area TEGA.

In some embodiments, a thickness FITH of the filler FI formed in the gap GA may be defined. Since the filler FI is disposed in the formed gap GA, the thickness FITH of the filler FI formed in the gap GA may vary in a direction from the through hole TH into the through hole edge area TEGA. For example, the thickness FITH of the filler FI formed in the gap GA may decrease in the direction from the through hole TH toward an interior of the gap GA within the through hole edge area TEGA.

In some embodiments, the common electrode remnant 173_D may be disposed between the substrate SUB and the encapsulation inorganic film TFE1. Due to the formed gap GA, a distance S173TH between the substrate SUB and the common electrode remnant 173_D may vary in the direction from the through hole TH into the through hole edge area TEGA. For example, a distance S173TH between the substrate SUB and the common electrode remnant 173_D may decrease moving away from the through hole TH and into the through hole edge area TEGA.

An upper light emitting layer remnant 172_Db may be disposed between the gap GA and the common electrode remnant 173_D. The upper light emitting layer remnant 172_Db may be disposed between the encapsulation inorganic film TFE1 and the filler FI.

A lower light emitting layer remnant 172_Da may be disposed between the gap GA and the substrate SUB. The lower light emitting layer remnant 172_Da may be disposed between the substrate SUB and the filler FI.

The lower light emitting layer remnant 172_Da and the upper light emitting layer remnant 172_Db according to one embodiment may be formed as a result of the separation of the light emitting element layers in the process of forming the gap GA. For example, the light emitting element layer may be separated into separate remnants in the process of forming the gap GA by arbitrarily tearing the end of the light emitting element layer.

In one embodiment, a distance S172TH between the substrate SUB and the upper light emitting layer remnant 172_Db may be defined. The upper light emitting layer remnant 172_Db may be included in the aforementioned encapsulation layer. The upper light emitting layer remnant 172_Db may include the first encapsulation inorganic film TFE1 and the second encapsulation inorganic film TFE3. Due to the formed gap GA, the distance S172TH between the substrate SUB and the upper light emitting layer remnant 172_Db may vary in the direction from an edge of the through hole TH into the through hole edge area TEGA. For example, the distance S172TH between the substrate SUB and the upper light emitting layer remnant 172_Db may decrease moving away from the through hole TH and into the through hole edge area TEGA.

In the display device according to some embodiments, the filler FI may be applied beyond the space of the gap GA, e.g., into a volume of the through hole TH in the process of forming the gap GA and disposing the filler FI in the gap GA. In this case, and as shown in FIG. 10, the filler FI may include a protrusion FIP protruding in the direction in which the through hole TH is disposed. In some examples, the protrusion FIP may be formed to cover at least a part of the lower light emitting layer remnant 172_Da.

Referring to FIG. 11, one side of the filler FI may coincide in cross-section with the edge TEG of the through hole TH. For example, a portion of the filler FI on the side of the through hole TH may be removed. When an optical device is placed in the through hole TH in such arrangements, the function of the optical device may be improved because no part of the filler FI overlaps the through hole TH.

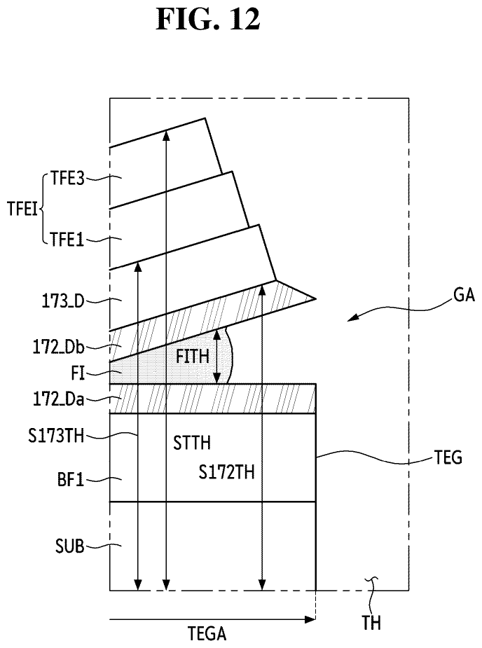

Referring to FIG. 12, the filler FI may fill at least a part of the gap GA without filling an entirety of the gap GA. In this manner, a volume of the filler FI may be less than a volume of the gap GA. In some examples, the fill amount for filler FI may be realized through removal of excess fill after the process of filling. The disposed filler FI serves to protect the display area from moisture (or oxygen) permeating through the through hole TH, and fills at least a part of the gap, thereby reducing the manufacturing costs. In addition, since a process of removing at least a part of the filler FI to improve the function of the optical device is required to get the benefit of minimizing obstructions in the through hole TH, the process efficiency may be improved.

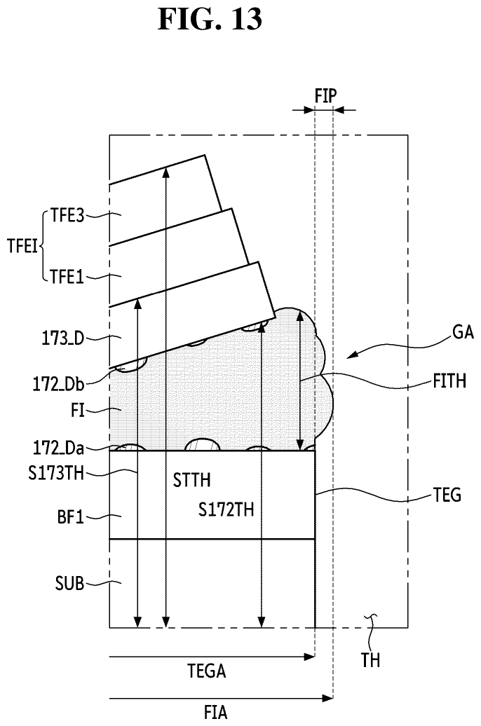

Referring to FIGS. 13 to 15, the illustrated embodiments represent other examples of the lower light emitting layer remnant 172_Da and the upper light emitting layer remnant 172_Db. The light emitting layer remnants 172_Da and 172_Db may exist discontinuously in a very thin and separated state. For example, at least a part of the upper light emitting layer remnant 172_Db may not exist and/or at least a part of the lower light emitting layer remnant 172_Da may not exist. These layer remnants may result due to tearing caused during the process of forming the gap GA. Alternatively, they may be in a state in which they have been at least partially removed arbitrarily by a laser or the like after the process of forming the gap GA.

Since the light emitting layer remnants 172_Da and 172_Db are very thin and at least a part thereof may not exist, the light emitting layer remnants 172_Da and 172_Db may not be clearly identified when the gap GA is observed through a micrograph.

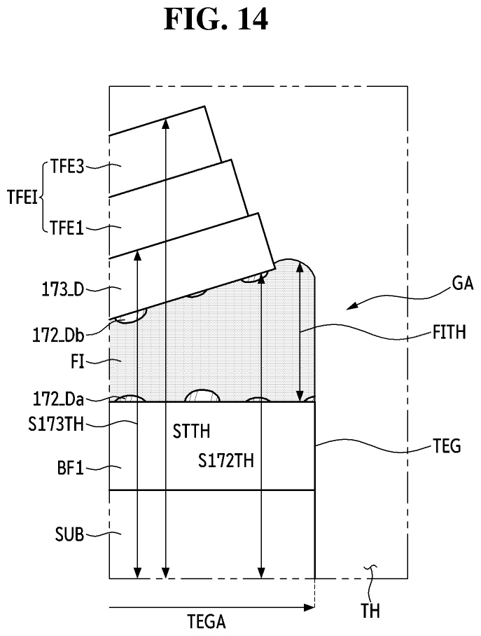

In the display device according to some embodiments, the filler FI may be applied beyond the space of the gap GA in the process of forming the gap GA and disposing the filler FI in the gap GA. In some examples, such as those shown in FIGS. 13 and 14, the filler FI may be formed to cover at least a part of the common electrode remnant 173_D.

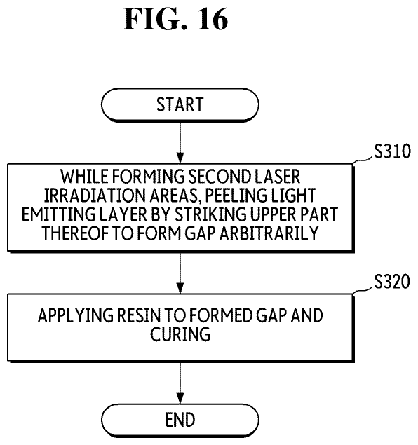

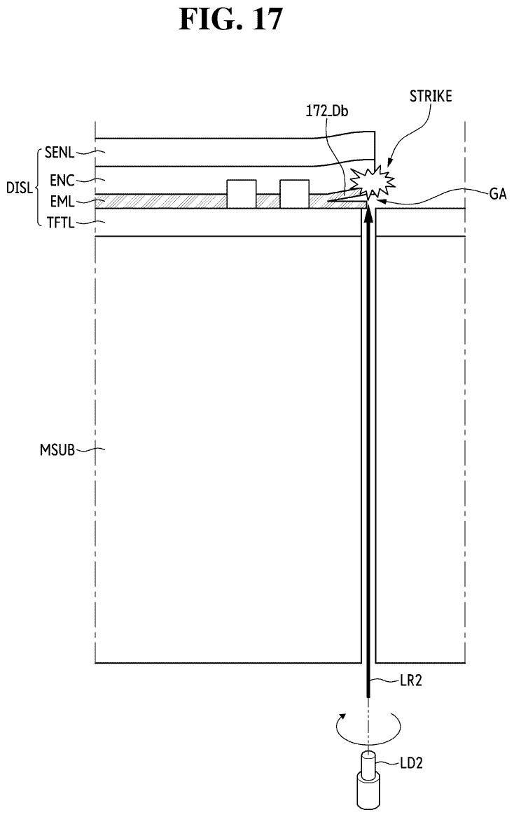

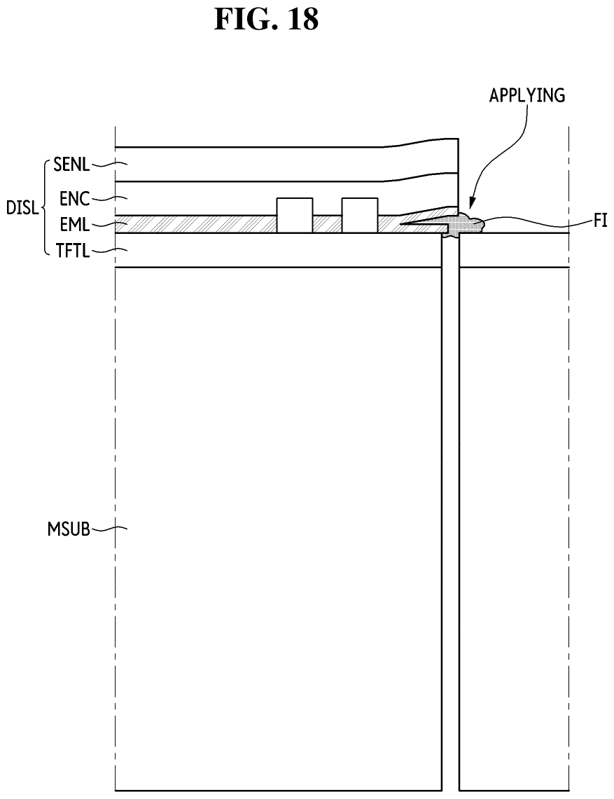

FIG. 16 is a flowchart showing a method of manufacturing a display device according to one embodiment of the present disclosure. FIGS. 17 to 18 are cross-sectional views illustrating steps in a method of manufacturing a display device according to one embodiment of the present disclosure.

Referring to FIGS. 16 and 17, a method of manufacturing may include, as one step, that a laser for forming a gap in the light emitting element layer EML may be irradiated using a laser device LD2. The laser may strike the light emitting element layer EML (step S310). For example, in a process in which a plurality of second laser irradiation areas for forming a through hole in each of display cells are formed by a second laser LR2, a laser irradiation process to form a gap may also be performed simultaneously for process efficiency. As the light emitting element layer EML is separated, the upper light emitting layer remnant 172_Db is formed, and thus a gap may be formed between the mother substrate MSUB and the encapsulation layer ENC.

Referring to FIGS. 16 and 18, as a subsequent step, the filler FI may be applied (step S320). For example, the filler FI may be applied to the formed gap and cured. In some embodiments, the application of the filler FI may be performed together with the cover resin application process for process efficiency.

The display device according to the embodiments of the present disclosure may be included in various electronic devices. An electronic device according to some embodiments may include the display device as described above, and may further include a module or device having an additional function in addition to the display device.

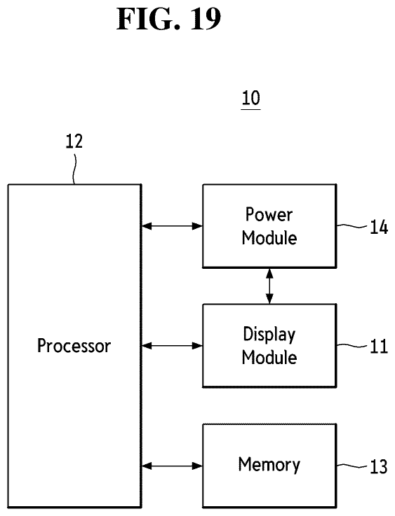

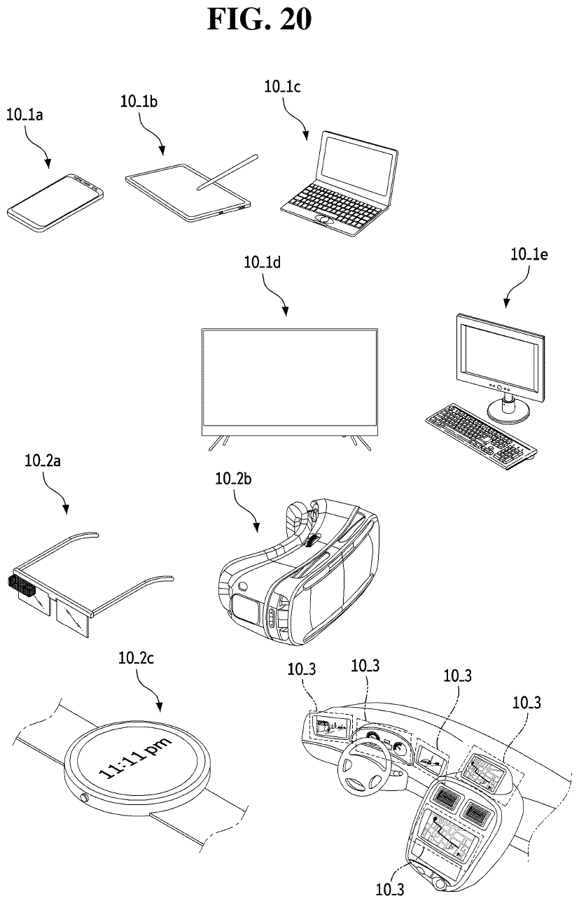

FIG. 19 is a block diagram of an electronic device according to one embodiment of the present disclosure. FIG. 20 includes schematic views of various electronic devices according to respective embodiments of the present disclosure.

Referring to FIG. 19, an electronic device 10 according to one embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device. Additionally, the power module 14 may include a power conversion module. The power conversion module may convert the power supplied by the power supply module to generate a power required for the operation of the electronic device 10.

At least one of the components of the electronic device 10 described above may be included in the display device according to the embodiments contemplated by the present disclosure. Further, some of the individual modules functionally included in one module may be included in the display device and some others may be provided separately from the display device. For example, the display device may include the display module 11, and the processor 12, the memory 13, and the power module 14 may be provided in the form of other devices in the electronic device 10 other than the display device.

Referring to FIG. 20, various electronic devices to which the display device according to the embodiments of the present disclosure is incorporated may include electronic devices for displaying images, such as a smartphone 10_1a, a tablet PC 10_1b, a laptop 10_1c, a television (TV) 10_1d, a desk monitor 10_1e, and the like. In addition, various electronic devices to which display devices according to the embodiments of the present disclosure are incorporated may include a wearable electronic device including a display module such as smart glasses 10_2a, a head mounted display 10_2b, a smart watch 10_2c, a vehicle electronic device 10_3 including a display module such as a dashboard of a vehicle, a center fascia, or a center information display (CID) of the dashboard, and a room mirror display, and the like.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting.

What is claimed is:

1. A display device comprising:
a display panel including a substrate and an encapsulation inorganic film disposed on the substrate; and
a through hole defined in the display panel,
wherein a gap is defined in the display panel between one side of the substrate exposed by the through hole and one side of the encapsulation inorganic film exposed by the through hole.

2. The display device of claim 1, wherein the display panel further comprises:
a through hole edge area adjacent to the through hole; and
an inorganic encapsulation area comprising a first dam and a second dam, the inorganic encapsulation area being adjacent to the through hole,
wherein a distance between the through hole and the second dam is smaller than a distance between the through hole and the first dam,
wherein the through hole edge area is between the through hole and the second dam, and
wherein a distance between the substrate and the encapsulation inorganic film changes from an edge of the through hole into the through hole edge area moving away from the edge of the through hole.

3. The display device of claim 2, wherein the through hole edge area further comprises a filler disposed between the substrate and the encapsulation inorganic film.

4. The display device of claim 3, wherein a thickness of the filler changes from the edge of through hole into the through hole edge area moving away from the edge of the through hole.

5. The display device of claim 4, wherein the thickness of the filler decreases from the edge of the through hole into the through hole edge area moving away from the edge of the through hole.

6. The display device of claim 2, wherein the distance between the substrate and the encapsulation inorganic film decreases from the edge of the through hole into the through hole edge area moving away from the edge of the through hole.

7. The display device of claim 2, wherein the through hole edge area further comprises a common electrode remnant disposed between the substrate and the encapsulation inorganic film.

8. The display device of claim 7, wherein a distance between the substrate and the common electrode remnant changes from the edge of the through hole into the through hole edge area moving away from the edge of the through hole.

9. The display device of claim 8, wherein the distance between the substrate and the common electrode remnant decreases from the edge of the through hole into the through hole edge area moving away from the edge of the through hole.

10. The display device of claim 2, wherein the through hole edge area further comprises a light emitting layer remnant disposed between the substrate and the encapsulation inorganic film.

11. The display device of claim 10, wherein the through hole edge area further comprises a filler disposed between the substrate and the encapsulation inorganic film.

12. The display device of claim 11, wherein the light emitting layer remnant further comprises an upper light emitting layer remnant disposed between the encapsulation inorganic film and the filler.

13. The display device of claim 11, wherein the light emitting layer remnant further comprises a lower light emitting layer remnant disposed between the substrate and the filler.

14. The display device of claim 12, wherein the light emitting layer remnant further comprises a lower light emitting layer remnant disposed between the substrate and the filler.

15. The display device of claim 3, wherein the filler further comprises a protrusion that protrudes relative to the edge of the through hole.

16. The display device of claim 12, wherein a distance between the substrate and the upper light emitting layer remnant changes from the edge of the through hole into the through hole edge area moving away from the edge of the through hole.

17. An electronic device comprising:
a display device comprising:
a display panel including a substrate and an encapsulation inorganic film disposed on the substrate, the display panel defining a through hole formed therethrough; and
a power module configured to supply power to the display device,
wherein a gap is defined in the display panel between one side of the substrate exposed by the through hole and one side of the encapsulation inorganic film exposed by the through hole.

18. The electronic device of claim 17, wherein the display panel further comprises:
a through hole edge area adjacent to the through hole; and
an inorganic encapsulation area comprising a first dam and a second dam, the inorganic encapsulation area being adjacent to the through hole,
wherein a distance between the through hole and the second dam is smaller than a distance between the through hole and the first dam,
wherein the through hole edge area is between the through hole and the second dam, and
wherein a distance between the substrate and the encapsulation inorganic film changes in the through hole edge area with increasing distance from an edge of the through hole.

19. The electronic device of claim 18, wherein the through hole edge area further comprises a filler disposed between the substrate and the encapsulation inorganic film.

20. The electronic device of claim 19, wherein a thickness of the filler changes from the edge of the through hole into the through hole edge area moving away from the edge of the through hole.
